(19) United States
(12) Patent Application Publication
(10) Pub. No.: US 2010/0258189 A1
(43) Pub. Date: Oct. 14, 2010

(54) WRAPPED SOLAR CEL

(76) Inventor: Seamus Curran, Pearland, TX (US)

Correspondence Address: BROWN RUDNICK LLP, ONE FINANCIAL CENTER, BOSTON, MA, 02111, US

(21) Appl. No.: 12/669,370

(22) PCT Filed: Jul. 18, 2008
(86) PCT No.: PCT/US08/70502

§ 371 Date: Jun. 28, 2010

Related U.S. Application Data
(60) Provisional application No. 60/950,528, filed on Jul. 18, 2007.

(51) Int. Cl. H01L 31/0256; H01L 31/18; H01L 31/02

(52) U.S. Cl. 136/263; 438/64; 136/252; 257/E31.032; 257/E31.11

(57) ABSTRACT

A photovoltaic device comprising a photovoltaic cell and at least one layer, the photovoltaic ceil and at least one layer wrapped from the inside out to form the photovoltaic device having a vertical geometry is provided. The photovoltaic device can be a variety of shapes. These shapes include a cylinder, square, oval, rope, ribbon, oblong and rectangular. Generally, the photovoltaic cell has at least on semiconductor, a hirfi work-function electrode and a low work-function electrode.

### RELATED APPLICATION INFORMATION

This patent application takes the priority of U.S. Provisional Application No. 60/950,528, filed in the U.S. Patent and Trademark Office on Jul. 18, 2007. The entire contents are incorporated herein by reference.

### FIELD OF THE INVENTION

The present invention generally relates to a photovoltaic device and method of production of the photovoltaic device and more particularly, to a photovoltaic device that manages both charge and optics in an organic photovoltaic cell with multiple wrapped thin film layers, which are vertically oriented.

### BACKGROUND OF THE INVENTION

Plastic (polymer) materials have, for the last two decades, received considerable attention as potentially a new material of choice for photonic based electronics. Classically, optical properties of plastics and their composite derivatives have great potential as they can convert almost all resonant light into energy (charge carrier generation), their absorption can be tailored to the ideal band gap of 1.1 eV and simple and cost effective production techniques can be use to make thin films. Although the first plastic solar cells were fabricated about twenty years ago, the ability to match inorganic thin film photovoltaics in terms of efficiencies has failed. Despite the wealth of research into plastic and composite based photovoltaics, the best devices fabricated thus far have efficiencies of slightly over 5%. Clearly, there are fundamental problems still associated with organic photovoltaics that have to be addressed before they can advance to the levels achieved by their inorganic counterparts. The fundamental problems are as follows.

Charge Carrier Transport: Polymers and polymer composites can convert almost all resonant light into charge earners (electrons and holes or excitons), but carrier transport is poor. The reason is twofold. First, the exciton generated can only travel very short distances, typically about 50 nm, before being recombined and secondly organic based photovoltaics possess poor mobilities and conductivities. Consequently, polymer composite devices fabricated can only be made from ultra-thin semiconductor films (less than 250 nm).

Transparency Due to the necessity to have very thin films as a consequence of poor carrier transport properties, significant light is lost due to transparency.

Oxidation: Plastic based electronics require stringently controlled lab conditions to minimize oxygen contamination in the polymers and composites.

For over twenty years, photovoltaic cells fabricated from organic materials have taken the shape of traditional flat panel devices as used in contemporary inorganic devices. The issues inherent with organic based devices are obviously different than inorganics, yet persisting with the same design does not address and solve these problems. Thus, fiat panel designs like those generally used for the last twenty years are not efficient for organic photovoltaics and a new and more efficient design would be desirable. By using architectural changes, all three main issues stated above will be addressed.

### SUMMARY OF THE INVENTION

A photovoltaic device comprising a photovoltaic cell and at least one layer, the photovoltaic cell and at least one layer wrapped from the inside out to form the photovoltaic device having a vertical geometry is provided. The photovoltaic device can be a variety of shapes. These shapes include a cylinder, square, oval, rope, ribbon, oblong and rectangular. Generally, the photovoltaic cell has at least one semiconductor, a high work-function electrode and a low work-function electrode. The photovoltaic device can include a protective layer and/or a substrate. Additional layers can be included in the photovoltaic device. These layers can include a band bending layer and an electron transporting layer. The photovoltaic cell can have more than one semiconductor. Such semiconductors are linearly aligned.

A method of making a photovoltaic device is also provided according to the present disclosure. The method includes the steps of layering a photovoltaic cell and at least one additional layer and wrapping the cell and layer from the inside out to form a photovoltaic device having a vertical geometry. The step of wrapping generally forms a shape such as a cylinder, square, oval, rope, ribbon, oblong and rectangular. The photovoltaic cell has at least one semiconductor, a high work-function electrode and a low work-function electrode. A protective layer and/or a substrate layer may be an additional layer. Other layers can be included in the device such as a band bending layer and an electron transporting layer.

### BRIEF DESCRIPTION OF THE DRAWING

Various exemplary embodiments of the present invention will be described in detail, with reference to the following figures, wherein:

FIG. 1 is a plan view of a rectangular wrap embodiment according to the present disclosure;

FIG. 2 is a plan view of a rectangular wrap embodiment according to the present disclosure;

FIG. 3 is a plan view of a rectangular wrap embodiment according to the present disclosure;

FIG. 4 is a plan view of exemplary shapes the photovoltaic device can have according to the present disclosure;

FIG. 5 is a plan view of an exemplary embodiment of a p-n junction device in a photovoltaic cell before the wrap method occurs according to the present disclosure;

FIG. 6 is a plan view of an exemplary embodiment of a n-type Schottky junction device in a photovoltaic cell before the wrap method occurs in accordance with the present disclosure;

FIG. 7 is a plan view of an exemplary embodiment of a heterojunction device in a photovoltaic cell before the wrap method occurs in accordance with the present disclosure;

FIG. 8 is a plan view of an exemplary embodiment of p-type Schottky junction device in a photovoltaic cell before the wrap method occurs in accordance with the present disclosure; and

FIG. 9 is a perspective view of a method of manufacturing the photovoltaic device according to the present disclosure;

FIG. 10 is a perspective view of a method of inserting a lens at the top of the wrap according to the present disclosure;

FIG. 11 is an image of the flat panel during production with the array of different semiconductors before the wrap method takes place according to the present disclosure;

FIG. 12 is an image of the wrap photovoltaic device with a glass support structure in accordance with the present disclosure;

FIG. 13 is an image of the wrap photovoltaic device in accordance with the present disclosure;

FIG. 14 is an image of the wrap photovoltaic device in accordance with the present disclosure;

FIG. 15 is an image of the wrap photovoltaic device in accordance with the present disclosure;

FIG. 16 is a spectrum of the wrap (1 cm²) in accordance with the present disclosure versus a thin film semiconductor; and

FIG. 17 is a perspective view of the wrap device showing contacting in accordance with the present disclosure.

### DETAILED DESCRIPTION OF THE INVENTION

The present disclosure describes a photovoltaic device design that consists of one or more organic layers successively wrapped up in thin-film design. The device and method according to the present disclosure enable light and charge to be managed in such a way that successive organic (hybrid, doped or heterojunction) layers can be printed and subsequently wrapped in a variety of shapes including a cylinder, square, oval, rope, ribbon, oblong or rectangular geometry of successive device layers from small on the inside to large on the outside.

The design of the photovoltaic device according to the present disclosure allows the maintenance of a thin semiconductor film without suffering from substantial transparency issues. Also, the design of the photovoltaic device enables light to be contained within the various layers until most of the resonant (resonant to the semiconductor) light is absorbed. By wrapping the layers around, the photovoltaic device can have a vertical geometry but, can also have successive layers of semiconductors wrapped around each other. This design maximizes space and efficiency.

The design of the organic photovoltaic cell provides, in terms of semiconductor thinness (circa: 100 nm), the ideal film for getting the excitons out from the active semiconductor layer, while also addresses the transparency issue by capturing and confining all resonant light within the wrap design. This design allows for the maintenance of a thin semiconductor film thus reducing the change of losses through exciton recombination.

While the design of the photovoltaic device according to the present disclosure is particularly important, the development of a suitable blend for the thin film composite, which captures and converts the sun's optical spectrum is similarly important. The self assembly process required to enhance the absorption process of the organic blend is critical to achieve better till factors as well as improved transport properties. In one embodiment according to the present disclosure, a series of semiconductor layers are in a linear tandem placement within the wrapped photovoltaic device so that a series of ‘lines’ of semiconductors can be coated or printed. This increases the possibility of capturing more of the sun's solar spectrum.

By building the device from the inside out, oxygen contamination is minimized through the natural encapsulation method used when building the devices in a controlled environment. This wrap method is an improvement over the more traditional thin film flat panel m the format of a microscale optical concentrator.

The use of the wrap method according to the present disclosure, building the thin film from the inside out in multiple layers addresses exciton thin film requirements, transparency and encapsulation needs. Further, the wrap based design maintains the organic thin film needs for removing excitons generated, but not at the cost of increasing transparency. Light is captured within the wrap based thin film in a similar manner to that used in large scale optical concentrators, so all resonant light can be used for efficient exciton generation and charge removal. In addition, by building the device from the inside out oxygen contamination is minimized through the natural encapsulation method used during fabrication. In one embodiment, the device comprises multiple layers such that the space used for the active layer is not confined to one layer, but is wrapped around maximizing the amount of semiconductor material that can be used to capture light efficiently in a small, cm², area.

The wrap design and method allows the production of the device according to the present disclosure using, for example, printer technology that can print successive lines of semiconductors, which can then be rolled up (for example, how paper is rolled up or folded from the inside out) and cut into thin slices, depending on requirements. Thus, one can have more semiconductor available to capture the resonant light, successive layers of different semiconductors arranged in a linear tandem arrangement than done elsewhere.

The photovoltaic device can comprise a photovoltaic cell, a protective layer and/or substrate. The photovoltaic cell has at least one semiconductor, a high work-function electrode and a low work-function electrode.

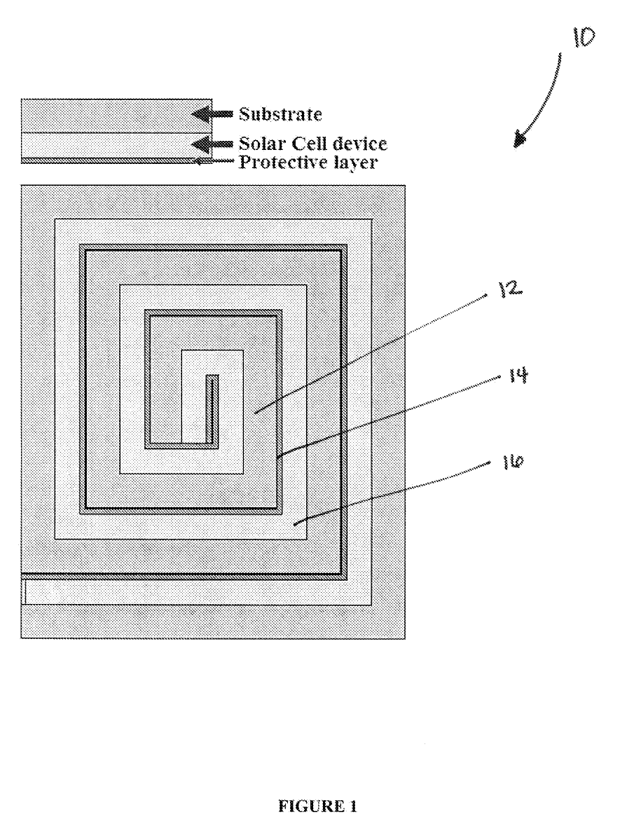

FIG. 1 is a topographic image of a rectangular wrapped photovoltaic device 10 where a substrate 12 and protective layer 14 are surrounding a photovoltaic cell 16. The photovoltaic cell 16 is wrapped around in a continuous loop in accordance with the present disclosure. The protective layer can be constructed of a variety of material, which include but are not limited to polycarbonate, polyethylene and polystyrene.

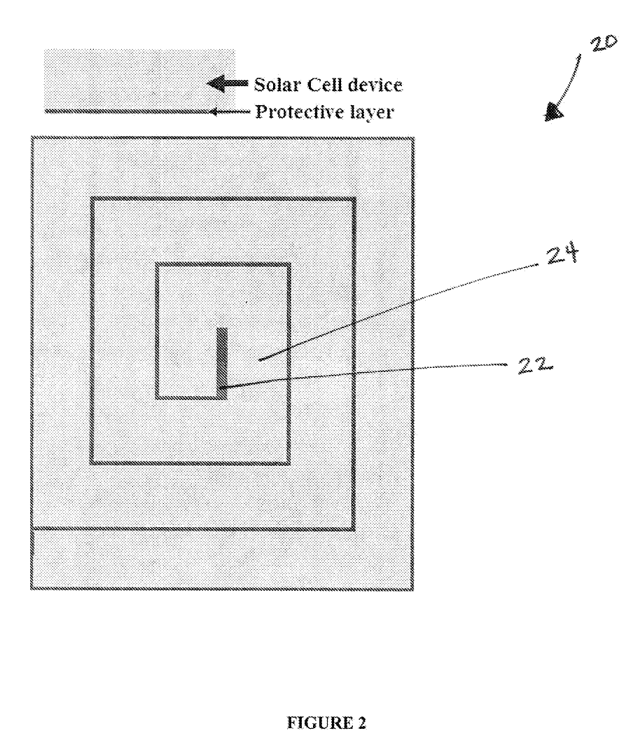

Similarly, FIG. 2 is a topographic image of a rectangular wrapped photovoltaic device 20 having protective layer 22 and a free standing film of a photovoltaic cell 24. The photovoltaic cell 24 is wrapped around in a continuous loop in accordance with the present disclosure.

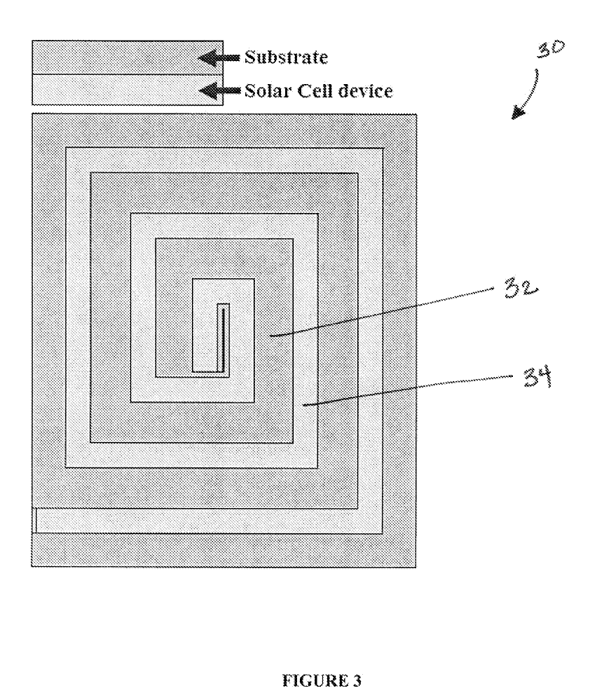

FIG. 3 depicts a topographic image of a rectangular wrapped photovoltaic device 30 having a substrate 32 that surrounds a photovoltaic cell 34. The photovoltaic cell 34 is wrapped around in a continuous loop in accordance with the present disclosure.

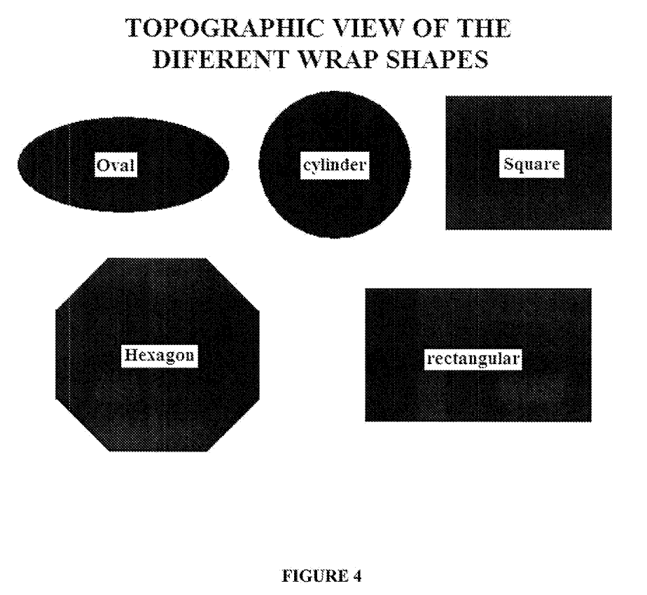

FIG. 4 shows image of the different shapes the photovoltaic device can have. The shapes include oval, cylinder, square, hexagon and rectangular, however, a large variety of shapes are contemplated by the present disclosure.

### Semiconductor

The semiconductor that can be used in the photovoltaic cell can be a variety of thicknesses and for example can be 50 nm to 250 nm.

The organic semiconductors that can he used in the photovoltaic cell according to the present disclosure include p-type conjugated polymers in a Schottky format (using a low work-function metal as the Schottky contact) and n-type conjugated polymers in a Schottky format (using a high work-function metal as the Schottky contact).

The semiconductor can consist of a variety of polymer or organic composite mixes. By way of example, the semiconductor can consist of polymer and up-converter mixed together in a heterojunction mix; polymer and fullerene mixed together in a heterojunction mix; and polymer and dye molecule mixed together in a heterojunction mix; polymer and carbon nanotube (single walled nanotube SWNT or multi walled nanotube MWNT) mixed together in a heterojunction mix; polymer and doped carbon nanotube mixed together in a heterojunction mix.

Further, the semiconductor can consist of a p-type polymer and n-type inorganic nanotube mixed together in a heterojunction mix; n-type polymer and p-type inorganic nanotube mixed together in a heterojunction mix; p-type polymer and n-type quantum dot mixed together in a heterojunction mix; n-type polymer and p-type quantum dot mixed together in a heterojunction mix; p-type polymer and n-type quantum well mixed together in a heterojunction mix; and n-type polymer and p-type quantum well mixed together in a heterojunction mix and p-n junction (the p can be polymer, or non-conjugated polymer host for a p-type quantum well or quantum dot) while the n can be polymer, fullerene or non-conjugated polymer host for a n type quantum well or quantum dot).

The semiconductor can be produced by a variety of processes. For example, the semiconductor can be printed, spray coated, wet spinning, dry spinning (for certain mixes), gel spinning, evaporated (such as in the case of C60 or C70), doctor blading or drop cast.

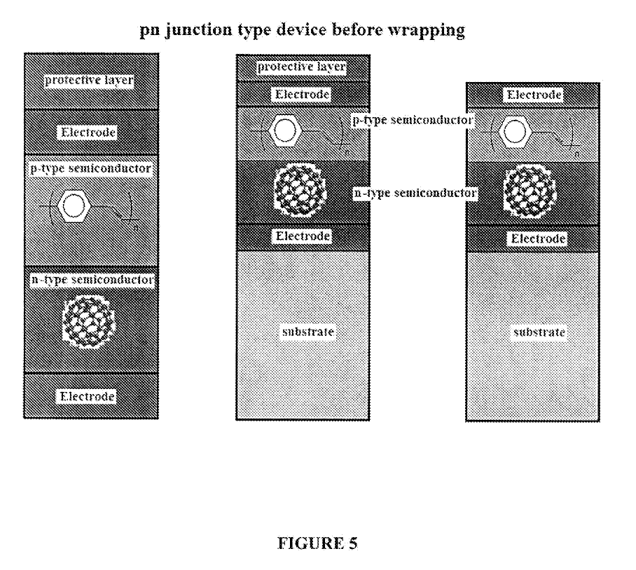

FIG. 5 is an example of the p-n junction device in the photovoltaic cell before the wrapping process takes place. This includes a p-type semiconductor, an n-type semiconductor and metal contacts to make a standard p-n junction.

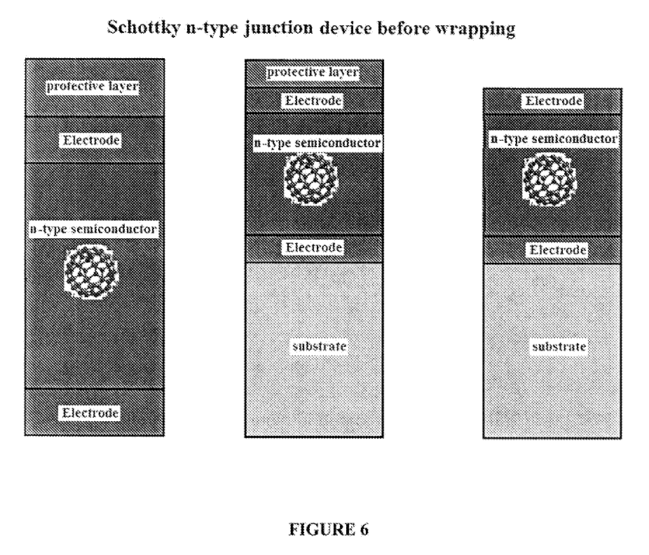

FIG. 6 depicts an example of the n-type Schottky junction device in the photovoltaic cell before the wrapping process takes place. In this case, the n-type semiconductor makes a Schottky contact with the high work-function metal, while the low work function metal forms an ohmic contact with the n-type semiconductor.

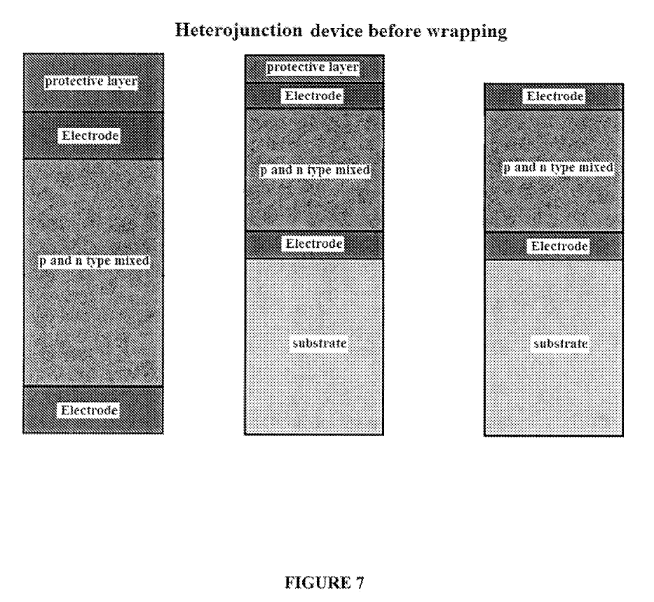

FIG. 7 is an example of the heterojunction device in the photovoltaic cell before the wrapping process takes place. In this case, the heterojunction form a Schottky contact with the dominant host material (normally a p-type) and suitable work-function metal, while the other metal contact forms an ohmic contact with the heterojunction semiconductor.

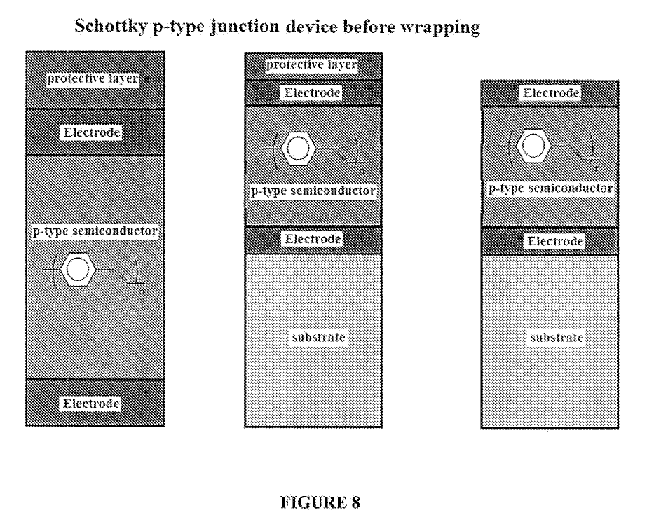

FIG. 8 depicts an example of the p-type Schottky junction device in the photovoltaic cell before the wrapping process takes place. In this case, the p-type semiconductor makes a Schottky contact with the low work-function metal, while the high work function metal foul's an ohmic contact with the p-type semiconductor.

### Layered Structure

The deposition of the photovoltaic can be accomplished on a plastic substrate that can be as thin as 1 mm and as thick as 1 cm. The plastic substrate can be a variety of materials including polycarbonate, polyethylene and polystyrene.

The electrodes used in the photovoltaic cell according to the present disclosure can consist of a high work-function and low work-function material. At least one of these electrodes should be semi-transparent or transparent. Examples of the high work-function metals can include, but not limited to gold, platinum, palladium or indium oxide (ITO). The work-function will likely be higher than −4.8 eV and except for ITO can be as thin as approximately 10 nm, and as thick as approximately 1 μm. In the case of ITO, it will have a surface conductivity as low as 1 ohms/sq and as high as 200 ohms/sq. The low work-function metal can include aluminum, alloys of MgIn or a variety of other such low work function alloys. The low-work functions for example, can be lower than −4.4 eV and can be as thin as approximately 10 nm, and as thick as approximately 1μm.

The photovoltaic device according to the present disclosure can include a variety of layers. For example, band bending layers can be included in the design, and be comprised of materials such as LiF or MgF. Desirably, these layers should not be more than approximately 2 nm thick. Similarly, electron transporting layers can be included, and can be Poly(3,4-ethylenedioxythiophene)-tetramethacrylate (PEDOT) or nanocomposites consisting of carbon nanotube or doped carbon nanotube or carbon fiber or grapheme in a conjugated or non-conjugated polymer host. The conductivities of this layer can range from approximately 10⁻⁴ S/cm to 10³ S/cm.

A top contact layer can be added to the top metal contact and this can be made from a non-conducting polymer. For example, the non-conducting polymer can be polycarbonate, polyethylene and polystyrene. Desirably, the thickness will be no less than approximately 50 nm and no thicker than approximately 1 mm.

The polymer is generally soluble in solvent suited to depositing a substantially even layer (variations no more than 20 nm) throughout the thin film. The solvents used must also be suitable for depositing heterojunction architectures maintaining ideal dispersion of the two mixes.

The bottom of the wrap device can have a reflective substrate such as for example, a mirror, lens or prism, that can be planar or conical in shape (upwards or downwards).

### Architecture

Once the layers are laid down in a sandwich cell manner, the sheet photovoltaic device can be wrapped in either a tubular form or wrapped in rectangular boxes from very small on the inside and growing successively larger as the photovoltaic device is wrapped. This wrapping process will provide the shape of the photovoltaic device as described above.

The length of the wrap can be from approximately 0.1 mm to 10 cm. The diameter can be from approximately 0.1 mm to 10 m.

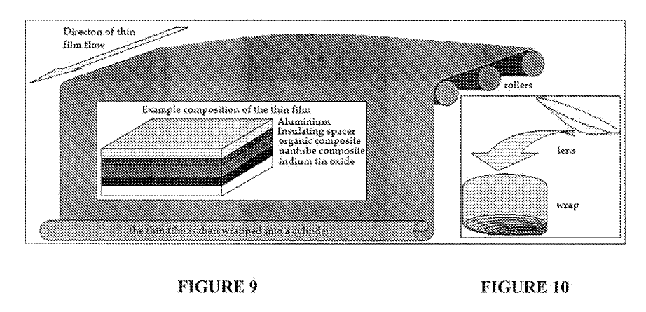

FIG. 9 illustrates a cylinder wrap and method of production. For example, the organic semiconductor is deposited (such as using a printing mechanism) on a metal (ITO can be considered a metal surface in this case) to a thickness of 100 to 200 nm, depending on the organic semiconductor. A top metal electrode is then deposited on the semiconductor, forming the photovoltaic cell. The device can then be wrapped (cylinder or rectangular for instance) into a geometry as shown from FIG. 4.

FIG. 10 depicts a method of inserting a lens at the top of the wrap in accordance with the present disclosure. The lens can be mechanically deposited on the top of the device.

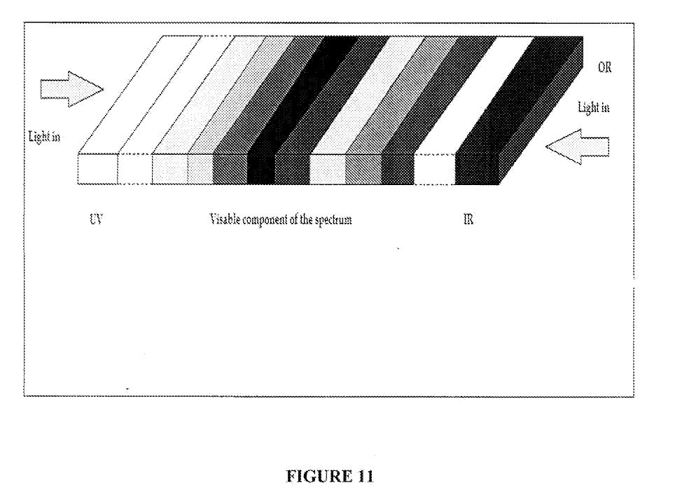

FIG. 11 is an image of the flat panel during production with the array of different semiconductors before the wrapping process. The number of semiconductors used is dependant on how much spectral overlap is desired or needed. The semiconductor is made up of multiple lines of absorbing layers. Each one tailored to absorb as much of the resonant spectrum. When printed like this, they can he lined up in a row as shown in FIG. 7 to absorb the IP, visible and UV light. While each layer is composed of a different material, provided the layers are kept below 200 nm, the exciton from each layer has a chance of getting out.

Thus, even if each line itself is only 1-2% efficient, by having all of them in a row as depicted in FIG. 11, the overall spectrum overlap can be added and produce a cell that has multiple wrap tandem arrangements anywhere from 2% to 40% depending on the number of printed lines laid.

The design of the device according to the present disclosure can also include an inner support structure such as a glass/polymer fiber as long it does not absorb any light. This inner support structure helps in managing the production of the weave and can also be used to house the metal electrode.

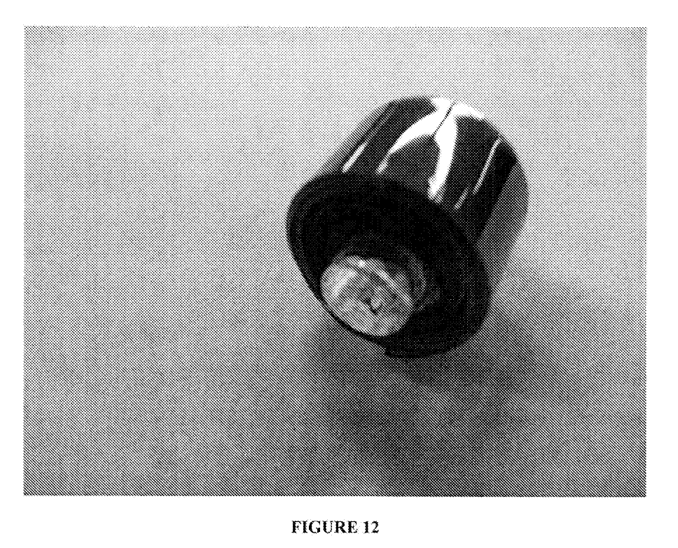

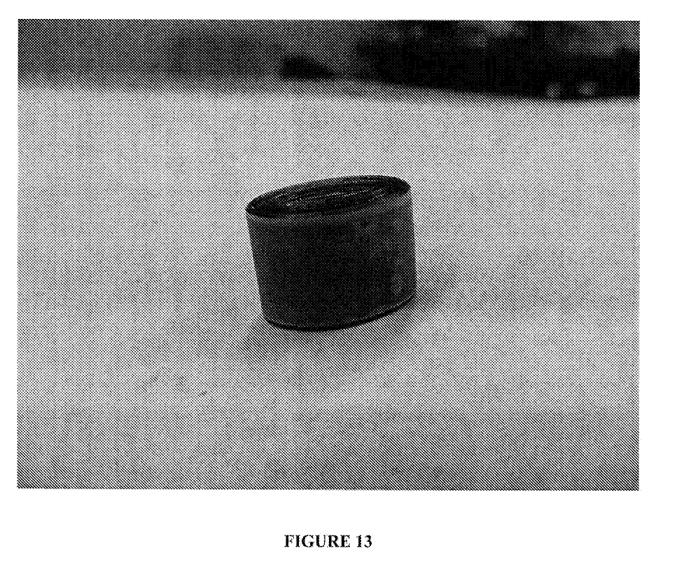

The photovoltaic cell and additional layers can also be wrapped around an initial glass support to give mechanical aid to the system. FIG. 12 depicts a photovoltaic device wrapped around a glass support in accordance with the present disclosure. The first layer is attached to the glass rod but the second is then tightly wrapped around the first and so on until the ideal diameter is achieved. Otherwise, the device can be simply wrapped around as shown in FIG. 13.

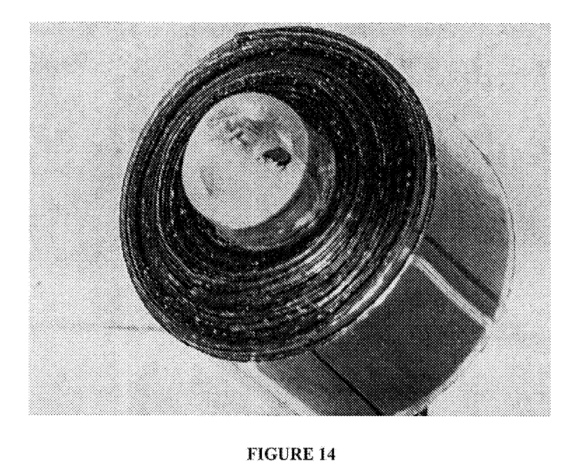

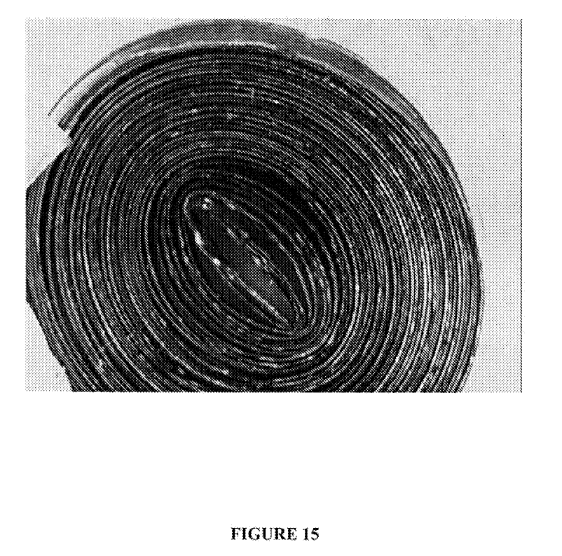

FIG. 14 and FIG. 15 are images of the wrapped photovoltaic device in accordance with the present disclosure.

The base of the photovoltaic devices can contain a mirror to reflect any light that gets through the layers back into the wrap. The mirror can be planar, or serrated such as found in Fresnel lens shapes so that the reflection is not directly back upwards but at an odd angle ensuring the light can ‘bounce’ back into the device to be absorbed resonantly.

The substrate layer can be made of polycarbonate, polystyrene or polystyrene and can contain fluorescent dyes (examples include but not limited to eosine or polyamides etc), quantum dots (examples include but not limited to sulphide (PbS), cadmium telluride (CdTe), cadmium sulphide (CdS), led selenium (PbSe) and cadmium selenide (CdSe)), quantum well structures (examples include GaInP and InGaAs/CaAs) or up converters (include but not limited to the family of inorganic ox.sulphides). This can be used as an aid to change the off resonant light into resonant light that the semiconductor can absorb.

A variety of p-type polymers can be used in accordance with the present disclosure such as poly(3-hexylthiopene) (P₃HT) which has been successful in recent times, as well as poly-3-octylthiophene (P₃OT), poly(2-methoxy-5-(2′-ethylhexyloxy-p-phenylenevinylene)] (MEH-PPV), poly [2-methoxy-5-(3′,7′-dimethyl-octyloxy)]-p-phenylene-vinylene (MDMO-PPV) and sodium poly[2-(3-thienyl)-ethoxy-4-butylsulphonate] (PTEBS) as the host polymers. PEDOT can b replaced by gRAFT polymerized nanotubes using polystyrene as the raft polymer. In this case the loadings of the nanotubes can be less than 1% weight, conductivities achieved up to 30 S/m and the material s perfectly transparent (Curran et al, JMR 2006). If higher conductivities are needed composites with well., dispersed but no acid treated nanotubes can also be added to get conductivities beyond 100 S/M.

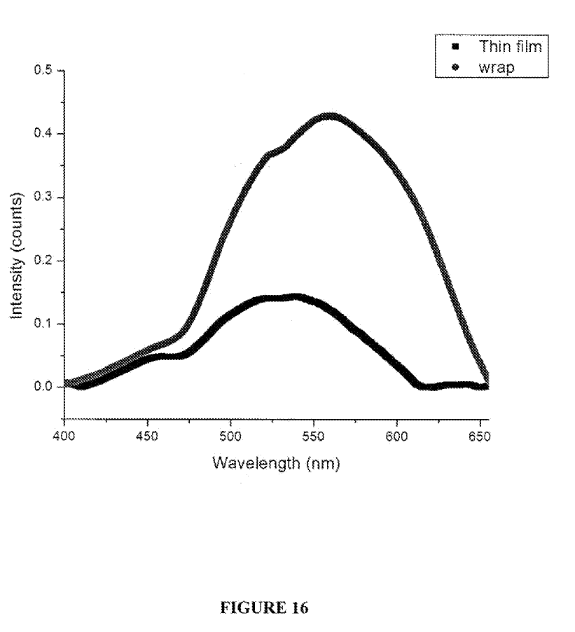

FIG. 16 is a spectrum of the wrap (1 cm²) in accordance with the present disclosure versus a thin film semiconductor. The wrap design ensures more light is absorbed than through normal planar devices. This design provides more resonant light absorbance per cm² than has been the case in previous organic semiconductor photovoltaics.

### Contacting

The inner electrode can be contacted to one terminal, while the second outer electrode will be contacted to the other terminal. The contact can be a metal bar (strip or nub) or wire.

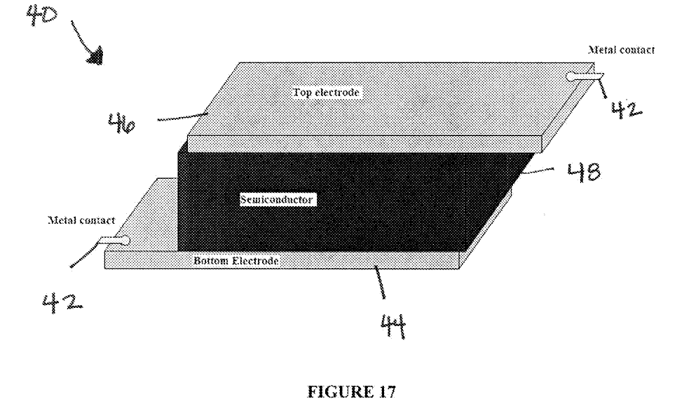

FIG. 17 illustrates that contacting can be done by placing a wire or metal stub at different points on a photovoltaic device 40. For example, as shown in FIG. 11, a metal contact 42 can be placed on each a bottom electrode 44 and a top electrode 46. A semiconductor 48 is between each of the metal contacts 42.

### Light Capturing

The light can be captured by simply illuminating the top of the device, or using a form of optical concentrator affixed on top of the photovoltaic cell wrap.

What is claimed is:

1. A photovoltaic device comprising:
a photovoltaic cell and at least one layer, the photovoltaic cell and at least one layer wrapped from the inside out to form the photovoltaic device having a vertical geometry.

2. The photovoltaic device of claim 1, wherein the shape of the wrapped photovoltaic device is selected from cylinder, square, oval, rope, ribbon, oblong and rectangular.

3. The photovoltaic device of claim 1, wherein the photovoltaic cell comprises at least one semiconductor, a high work-function electrode and a low work-function electrode.

4. The photovoltaic device of claim 1, wherein the at least one layer is a protective layer.

5. The photovoltaic device of claim 1, wherein the at least one layer is a substrate.

6. The photovoltaic device of claim 1, wherein the photovoltaic cell comprises a hand bending layer.

7. The photovoltaic device of claim 1, wherein the photovoltaic cell comprises an electron transporting layer.

8. The photovoltaic device of claim 1, wherein the photovoltaic cell comprises more than one semiconductor, the semiconductors being aligned linearly.

9. A photovoltaic device comprising;
an organic photovoltaic cell having at least one semiconductor wrapped from the inside out having a vertical geometry, the photovoltaic device having at least a protective layer and a substrate.

10. The photovoltaic, device of claim 9, wherein the shape of the wrapped photovoltaic device is selected from cylinder, square, oval, rope, ribbon, oblong and rectangular.

11. The photovoltaic device of claim 9, wherein the photovoltaic cell comprises at least two semiconductors, a high work-function electrode and a low work-function electrode.

12. The photovoltaic device of claim 1 wherein the photovoltaic cell further comprises a band bending layer.

13. The photovoltaic device of claim wherein the photovoltaic cell further rises an electron transporting layer.

14. A method of making a photovoltaic device comprising the steps of:
layering a photovoltaic cell and at least one additional layer; and
wrapping the cell and layer from the inside out to form a photovoltaic device having a vertical geometry.

15. The method of claim 14, wherein the wrapping forms a photovoltaic device having a shape selected from cylinder, square, oval, rope, ribbon, oblong and rectangular.

16. The method of claim 14, wherein the photovoltaic cell comprises at least one semiconductor, a high work-function electrode and a low work-function electrode.

17. The method of claim 14, wherein the at least one layer is a protective layer.

18. The photovoltaic device of claim 14, wherein the at least one layer is a substrate.

19. The method of claim 14, wherein the photovoltaic device includes a band bending layer.

20. The method of claim: 14, wherein the photovoltaic device includes an electron transporting layer.
